(19) United States
(12) Patent Application Publication
(10) Pub. No.: US 2008/0076226 A1
(43) Pub. Date: Mar. 27, 2008

(54) Apparatus and method of backside anneal for reduced topside pattern effect

(76) Inventors: Karson L. Knutson, Beaverton, OR (US); Robert James, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/525,770

(22) Filed: Sep. 22, 2006

(51) Int. Cl. H01L 21/336

(52) U.S. Cl. 438/308

(57) ABSTRACT

Embodiments of an apparatus and methods for heating an absorbing layer on a wafer by exposing the wafer to an electromagnetic energy source are generally described herein. Other embodiments may be described and claimed.

### FIELD OF THE INVENTION

The field of invention relates generally to the field of semiconductor integrated circuit manufacturing tools and, more specifically but not exclusively, relates to thermal anneal tools with a radiation energy source incident on the backside of a wafer for heating a device layer situated on a top or opposite side of the wafer, thereby minimizing device layer pattern effect.

### BACKGROUND INFORMATION

The semiconductor fabrication process is a series of steps designed to coat, etch, and modify a substrate to produce a layout of die. One such typical process is the radiation anneal process wherein the temperature of the semiconductor wafer or workpiece, as the case may be, is brought to a sufficient elevated temperature for the radiation anneal process to be effective. However, there are many characteristic variations in semiconductor devices such as die layout, topside pattern, and film stacks in a device layer, which tend to make each semiconductor device respond differently based on wafer specific characteristics. For example, one wafer may contain areas of die that may become a microprocessor in subsequent processing. In another example, a wafer may contain areas of die that may become flash memory devices in subsequent processing stages. Therefore, as between the two wafers, there may be a multitude of variations in patterns on the wafer topside. These differences may result in each wafer requiring more or less energy to achieve an adequate anneal temperature.

The method used to deliver energy to the device layer can also affect how heat is distributed among areas of the device layer, resulting in temperature variations within each die. In a typical radiation anneal process, a high intensity lamp is used to radiate thermal energy into the patterned side of the wafer. Meanwhile, the temperature of the backside of the wafer is monitored using a non-contact probe. The process is normally controlled by measuring radiation emitted by the backside of the wafer with the non-contact probe and adjusting the amount of energy delivered to the topside of the wafer by the radiation heat source to achieve an averaged peak surface temperature.

Wafer to wafer variations, as discussed previously, can significantly affect the peak surface temperature achieved in the process of each wafer. Also, variations in the amount of light originating from the lamp source can also lead to unacceptable variations in the peak surface temperature. Too much energy can lead to intense heating of localized regions within the device layer, which can compromise transistors, capacitors, and other devices, making them inoperable. Too little energy can also result in insufficient device layer temperature, potentially making devices inoperable.

### BRIEF DESCRIPTION OF THE DRAWINGS

The present invention is illustrated by way of example and not as a limitation in the figures of the accompanying drawings, in which

FIG. 1 is an illustration of one embodiment of an electromagnetic energy emitter to emit electromagnetic energy to an un-patterned backside of a wafer.

FIG. 2 is an illustration of another embodiment of an electromagnetic energy emitter to emit electromagnetic energy over a backside of wafer in an atmospherically controlled chamber.

FIG. 2A is a cross-sectional view of the wafer taken through section line A-A of FIG. 2. This view illustrates the electromagnetic energy to be moved over the backside of the wafer.

FIG. 3 is an illustration of one embodiment of a wafer support structure to support a wafer to be heated by electromagnetic energy moved over an un-patterned backside of the wafer.

FIG. 4 is a flowchart describing one embodiment of a method to heat a device layer on second side of a wafer by moving electromagnetic energy over a first side of the wafer.

### DETAILED DESCRIPTION

An apparatus and method for heating an absorbing layer on a wafer by exposing the wafer to an electromagnetic energy source is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

There is a general need for heating a device layer on a wafer in a uniform manner that is largely independent of a device layer structure. Heating of a device layer may be used for dopant activation anneal processes, salicide formation processes, reflow processes, and deposition processes. By heating the device layer in a uniform manner using an adjacent absorbing layer, localized heating of regions within the device layer may be avoided, thereby increasing a yield of discrete devices within a wafer die while enabling maximum device performance. One embodiment of a method for heating an absorbing layer on a substrate comprises placing a substrate with an un-patterned surface on a first side proximate to an electromagnetic energy emitter, wherein an absorbing layer and a device layer are formed on a second side of the substrate. Electromagnetic energy is emitted incident to the first side of the substrate such that a portion of the electromagnetic energy incident to the first side of the substrate is absorbed by an absorbing layer.

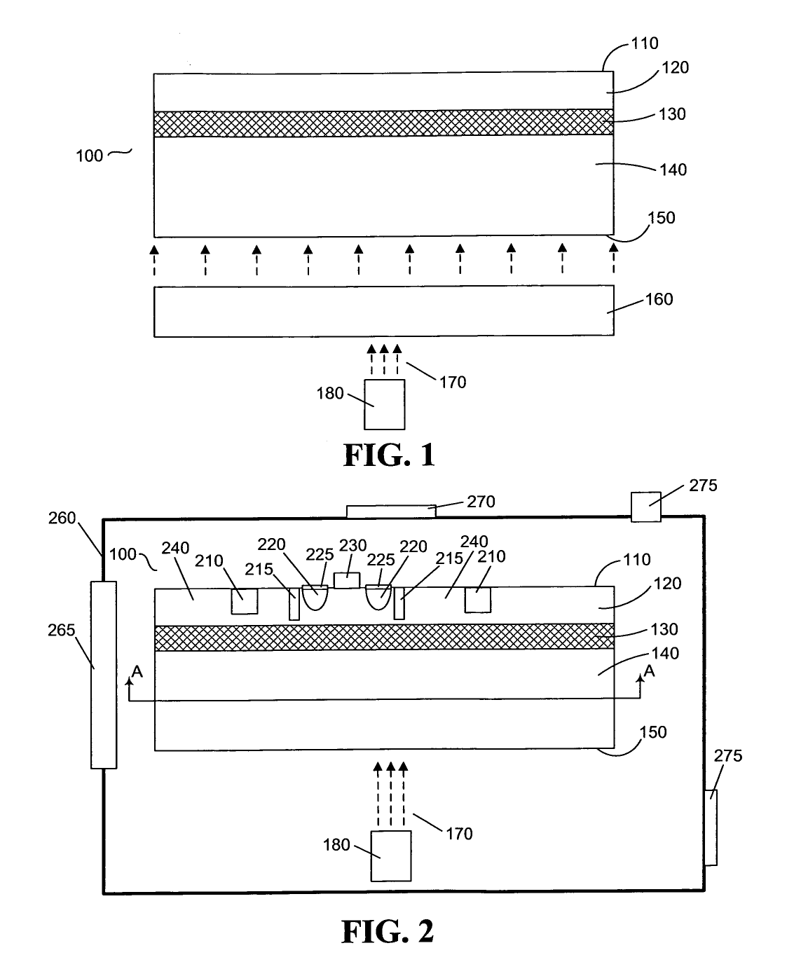

The illustration in FIG. 1 is one embodiment of a side view of a wafer 100 comprised of a substrate 140, a device layer 120, and an absorbing layer 130 situated between the substrate 140 and the device layer 120. The wafer 100 has a first side 150 that may be an un-patterned and substantially flat bare silicon surface with a native oxide film and a second side 110 which is a top surface of the device layer 120. A film may also be formed on the first side 150 containing a material such as silicon nitride, silicon dioxide, or silicon oxy-nitride. The substrate 140 is a high resistivity material such as intrinsic monocrystalline silicon, lightly doped monocrystalline silicon with a concentration of approximately 1E16 atoms/cm³ or less, or another semiconducting material such as silicon germanium, gallium arsenide, gallium phosphide, and indium phosphide that is largely transparent to electromagnetic energy 170 emitted in the approximate range between 1 and 3 microns in wavelength. The absorbing layer 130 is a film grown on the substrate 140 at a thickness between one and five microns comprising a heavily doped epitaxy with an approximate dopant concentration ranging between 5E20 and 1E22 atoms/cm³.

Alternatively, the absorbing layer 130 is a region formed at a thickness between one and five microns comprising a heavily doped and annealed ion implant layer with an approximate dopant concentration ranging between 5E20 and 1E22 atoms/cm³. In another embodiment, the absorbing layer 130 is a region formed at a thickness between one and five microns comprising a heavily doped layer formed from a solid source dopant. In this embodiment, a solid material containing the target dopant is placed adjacent to the substrate 140 and heated to diffuse dopant material into the substrate 140 to create the absorbing layer 130. The device layer 120 is formed adjacent to the absorbing layer 130, in a manner that provides heat transfer from the absorbing layer 130 to the device layer 120, and comprises a lightly doped silicon epitaxial layer with a concentration of approximately 1E16 atoms/cm³ or less at a thickness of approximately one to four microns.

The electromagnetic energy 170 is emitted by an electromagnetic energy emitter 180 that may be a neodymium yttrium laser, a neodymium glass laser, an argon laser, a helium neon laser, a chromium forsterite laser, or an erbium glass laser, though the embodiment is not so limited. The electromagnetic energy 170 emitted by the electromagnetic energy emitter 180 may be modified or redirected by a lens system 160 so that the electromagnetic energy 170 is distributed across the first side 150 of the wafer 100.

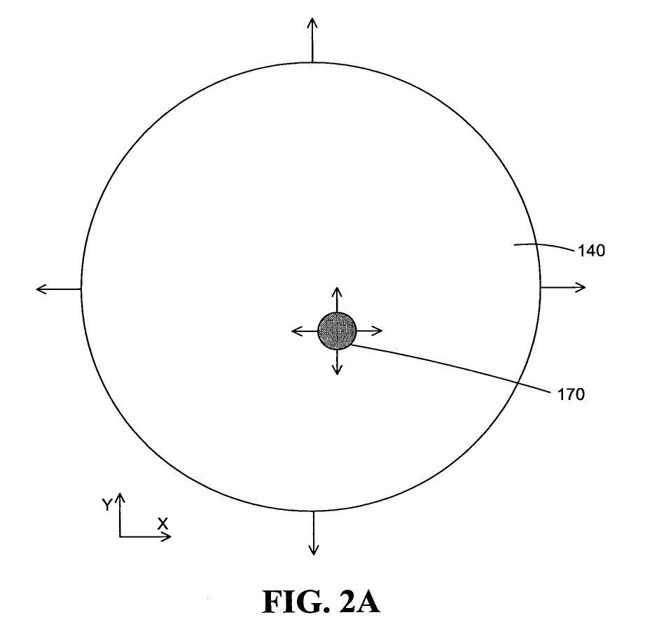

FIG. 2 is an illustration of an embodiment of an electromagnetic energy emitter 180 to emit electromagnetic energy 170 over a first side 150 of wafer 100 in an atmospherically controlled chamber 260. The atmospherically controlled chamber 260 comprises a door 265 such as a slit valve, a piston type valve, a rotating flap, a removal panel, or any type of mechanism, such as a positive pressure differential, known to one skilled in the art that may allow entrance and exit of the wafer 100 while partially or completely sealing the atmospherically controlled chamber 260.

The atmospherically controlled chamber 260 further comprises an input port 270 to deliver gases or vapors such as air, nitrogen, nitrous oxide, oxygen, or argon to a controlled atmosphere within the atmospherically controlled chamber 260. The controlled atmosphere may be monitored using a pressure sensing device 275 such as a Bourdon gauge, a thermocouple gauge, a Pirani gauge, or a capacitance manometer. The controlled atmosphere may be moderated using methods known to one skilled in the art, such as by moderating input gases from the input port 270 while moderating exhaust gases through an exhaust valve 275.

A large portion of the electromagnetic energy 170 emitted by the electromagnetic energy emitter 180 may pass through the high resistivity substrate 140 without being absorbed. The heavily doped absorbing layer 130 will absorb a large portion of the electromagnetic energy 170 at a faster rate than the absorbing layer 130 can dissipate the electromagnetic energy 170 and the absorbing layer 130 will increase in temperature. The absorbing layer dissipates a portion of the electromagnetic energy 170 by transferring a portion to heat and anneal an adjacent device layer 120. The device layer 120 may comprise discrete devices such as transistors and capacitors fabricated with regions of materials such as ion implant dopant regions 220, dielectric regions 215, polysilicon regions 230, metal regions 210, epitaxial regions 240, or regions of silicide 225 in and on the device layer 120.

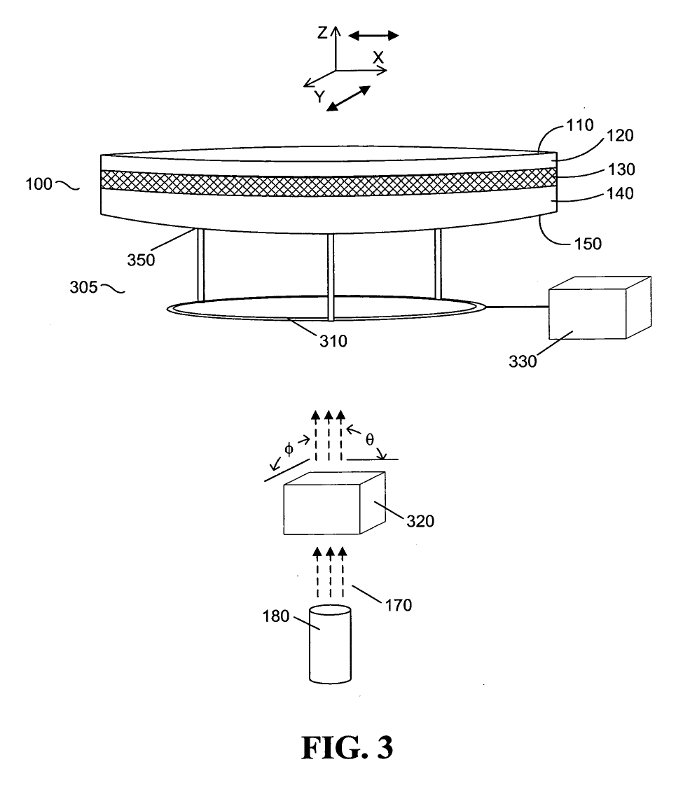

FIG. 2A is a cross-sectional view of the wafer 100 taken through section line A-A of FIG. 2 of the substrate 140. This view illustrates the electromagnetic energy 170 to be moved over the backside of the wafer 100. In this embodiment, the electromagnetic energy 170 is delivered to a portion of the substrate 140 and moved relative to the substrate 140 as illustrated in FIG. 3 in an X-Y plane. An electromagnetic energy emitter may be directly incident to the first side 150 of the wafer 100, meaning that the electromagnetic energy 170 travels from an electromagnetic energy emitter 180 to a first side 150 of the wafer 100 without traveling through an intermediate structure.

FIG. 3 is an illustration of one embodiment of a wafer support structure 305 to support a wafer 100 to be heated by electromagnetic energy 170 moved over an un-patterned backside, or first side 150 of the wafer 100. An electromagnetic energy emitter 180 is situated proximate to a proximal end 310 of a wafer support structure 305 and a wafer 100 is situated on a distal end 350 of the wafer support structure 305. The wafer support structure 305 may comprise three pins to support the wafer 100. Alternatively, the wafer support structure 305 may comprise a peripheral ring for contacting the first side, 150, near the edge, of the wafer 100. As another example, the wafer support structure 305 may comprise a platen, or a substantially planar plate to support the wafer 100. The wafer support structure 305 may be comprised of a material, that is substantially transparent to electromagnetic energy 170 emitted by an electromagnetic energy emitter 180, such as quartz, fused silica, sapphire, yttrium aluminum garnet, yttrium vanadate, erbium glass, magnesium fluoride, calcium fluoride, and barium fluoride.

The electromagnetic energy 170 is moved over the first side 150 of the wafer 100 to heat the absorbing layer 130. The device layer 120 is subsequently annealed by the adjacent absorbing layer 130. The electromagnetic energy 170 may be moved relative to the wafer 100 by a rastering system 320 to distribute electromagnetic energy across the first side 150 of the wafer 100. In one embodiment, the rastering system 320 evenly distributes electromagnetic energy 170 in a rastering movement over the first side 150 of the wafer 100 by moving the electromagnetic energy 170 though a theta angle (θ) along an X-direction and in a phi angle (φ) along a Y-direction. In another embodiment, the rastering system 320 distributes electromagnetic energy over the first side 150 of the wafer 100 by moving the electromagnetic energy 170 through the theta and phi angles in a predetermined pattern to selectively heat portions of the absorbing layer 130 and anneal portions of the device layer 120.

Alternatively or in combination with the rastering movement, the wafer support structure 305 may be moved in an X-direction, in a Y-direction, or in the X-direction and the Y-direction using a scanning system 330. The scanning system 330 may be a rotation mechanism that rotates the wafer support structure 305 around a central axis either inside or outside the diameter of the wafer 100. Alternatively or in combination with the rotation mechanism, the scanning system 330 may comprise linear drive mechanisms to move the wafer support structure 305 in an X-direction, in a Y-direction, or in the X-direction and the Y-direction so that the electromagnetic energy 170 may reach all areas of the absorbing layer 130. Alternatively an incident radiation pattern could span an X-Y block that is small relative to the wafer 100 and then be stepped and pulsed covering the entire wafer 100, block by block.

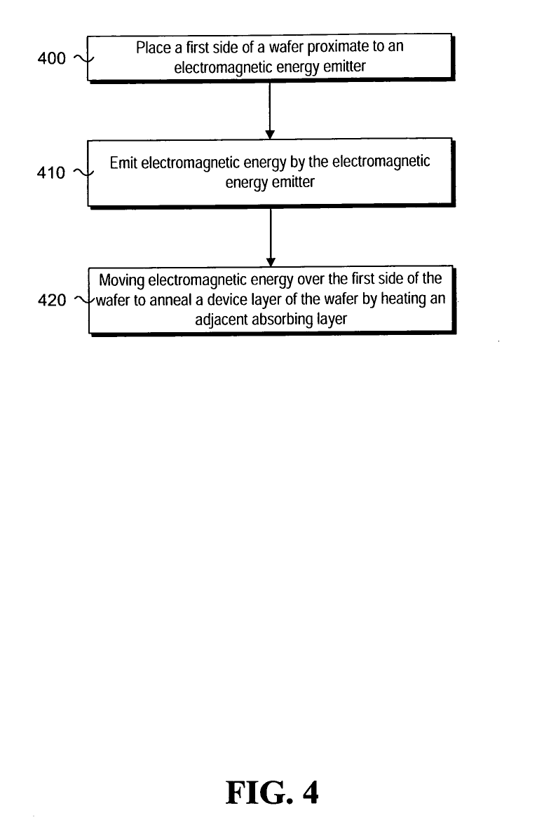

FIG. 4 is a flowchart describing one embodiment of a method to anneal a device layer 120 on second side 110 of a wafer 100 by moving electromagnetic energy 170 over a first side 150 of the wafer 100 illustrated in FIGS. 2 through 3. In element 400, a wafer 100 is placed proximate to an electromagnetic energy emitter 180. The wafer may be placed on a wafer support structure 305 either manually or through an automated process using a mechanism such as a robot or another automated mechanical system. Electromagnetic energy 170 is emitted by the electromagnetic energy emitter 180 in element 410 to heat an absorbing layer 130 and to anneal a device layer 120 that may comprise discrete devices such as transistors and capacitors fabricated with regions of materials such as ion implant dopant regions 220, dielectric regions 215, polysilicon regions 230, metal regions 210, or regions of silicide 225 in and on a device layer 120.

In element 420, the electromagnetic energy 170 is moved over the first side 150 of the wafer 100 to anneal a device layer 120 by heating an adjacent absorbing layer 130. The electromagnetic energy 170 may be moved relative to the wafer by scanning the wafer support structure 305 relative to the electromagnetic energy emitter 180, by rastering the electromagnetic energy 170 using a rastering system 320, by scanning the wafer 100 using a scanning system 330, or by scanning the wafer 100 and rastering the electromagnetic energy 170 using a scanning system 330 and a rastering system 320. The amount of electromagnetic energy 170 delivered to a wafer 100 may be controlled by methods known to one skilled in the art. For example, the amount of electromagnetic energy 170 may be controlled by characterizing input process parameters such as anneal time, absorbing layer 130 type, and laser supply power.

A plurality of embodiments of annealing a device layer on a wafer, in a uniform manner that is largely independent of a device layer structure, has been described. The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or a discrete device is the “top” surface of that substrate; the substrate may actually be in any orientation so that a “top” side of a substrate may be lower than the “bottom” side in a standard terrestrial frame of reference and still fall within the meaning of the term “top.” The terms “on” or “adjacent” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of heating an absorbing layer on a substrate, comprising:
situating a substrate with an un-patterned surface on a first side proximate to an electromagnetic energy emitter, wherein an absorbing layer and a device layer are formed on a second side of the substrate;
emitting electromagnetic energy incident to the first side of the substrate such that a portion of the electromagnetic energy incident to the first side of the substrate is absorbed by an absorbing layer.

2. The method of claim 1, wherein the absorbing layer comprises at least one of a doped epitaxy, an ion implant doped layer, and a solid source doped layer.

3. The method of claim 1, further including heating a device layer using the absorbing layer wherein the device layer comprises at least one of an ion implant doped region, a dielectric region, a polysilicon region, a metal region, an epitaxial region, and a silicide region.

4. The method of claim 1, wherein the electromagnetic energy emitter emits electromagnetic energy at a wavelength between 1.3 micron and 2 microns.

5. The method of claim 4, wherein the electromagnetic energy emitter is a neodymium yttrium laser, a neodymium glass laser, an argon laser, a helium neon laser, a chromium forsterite laser, or an erbium glass laser.

6. The method of claim 1, further including moving the electromagnetic energy emitter relative to the substrate.

7. The method of claim 6, wherein emitting electromagnetic energy incident to a portion of the first side of the substrate.

8. A method of heating a device layer with an absorbing layer on a substrate, comprising:
providing a wafer with a substrate on a first side, a device layer on a second side, and an absorbing layer situated between the substrate and the device layer;
moving electromagnetic energy from an electromagnetic energy emitter over the substrate so as to transmit substantially all of the electromagnetic energy through the substrate and absorb a portion of the electromagnetic energy by the absorbing layer and heating the device layer with the portion of the electromagnetic energy absorbed by the absorbing layer.

9. The method of claim 8, wherein the absorbing layer comprises at least one of a doped epitaxy layer, an ion implant doped layer, and a solid source doped layer.

10. The method of claim 8, further including locating the electromagnetic energy emitter and the wafer in an atmospherically controlled chamber.

11. The method of claim 10, wherein a chamber pressure within the atmospherically controlled chamber is between 10 Torr and 1000 Torr.

12. The method of claim 11, wherein an atmosphere within the atmospherically controlled chamber comprises at least one of nitrogen, nitrous oxide, oxygen, and argon.

13. An apparatus comprising:
an electromagnetic energy emitter proximate to a proximal end of a wafer support structure;
the wafer support structure, having a distal end for receiving a wafer comprising a substrate, being substantially transparent to electromagnetic energy emitted by an electromagnetic energy emitter; and
a system for moving electromagnetic energy emitted by the electromagnetic energy emitter relative to the wafer support structure.

14. The apparatus of claim 13, wherein the wafer support structure comprises a platen for contacting the backside of the substrate.

15. The apparatus of claim 13, wherein the wafer support structure is equipped to move relative to the electromagnetic energy emitter.

16. The apparatus of claim 13, wherein the system is provided to raster scan electromagnetic energy over a first side of the wafer.

17. The apparatus of claim 13, wherein the system is provided to move a square or rectangular laser beam in a step and pulse manner over a first side of the wafer.

18. The apparatus of claim 13, wherein the electromagnetic energy emitter is a neodymium yttrium, a neodymium glass, an argon, a helium neon, a chromium forsterite, or an erbium glass laser.

19. The apparatus of claim 13, wherein the electromagnetic energy emitter is provided to emit electromagnetic energy at a wavelength between 1.3 micron and 2 microns.

20. The apparatus of claim 13, wherein the wafer support structure comprises at least one of quartz, fused silica, and sapphire.
